(19) United States
(12) Patent Application Publication
(10) Pub. No.: US 2010/0043862 A1
(43) Pub. Date: Feb. 25, 2010

(54) Solar Panel Interconnection System

(76) Inventor: Steven Thomas Croft, Menlo Park, CA (US)

Correspondence Address: CASCIO & ZERVAS, 423 BROADWAY AVE., SUITE 314, MILLBRAE, CA, 94030-1905, US

(21) Appl. No.: 12/544,984

(22) Filed: Aug. 20, 2009

Related U.S. Application Data
(63) Continuation-in-part of application No. 12/121,602, filed on May 15, 2008.

(51) Int. Cl. H01L 31/042

(52) U.S. Cl. 136/244

(57) ABSTRACT

A solar panel interconnection system in which electrical interconnection distance is minimized irrespective of one of landscape or portrait panel orientation includes a first solar panel having first diagonally opposed corners, a first edge, a second edge and a tap to provide electrical connectivity thereto, and a second solar panel having second diagonally opposed corners, a first edge, a second edge and a tap to provide electrical connectivity thereto. The first edge and the second edge of the first solar panel extend from one of the first diagonally opposed corners and the tap on the first solar panel is disposed at the same corner thereof. The first edge and the second edge of the second solar panel extend from one of the second diagonally opposed corners and the tap on the second solar panel is disposed at the same corner thereof. The first solar panel and the second solar panel are disposed with either the first edge of each facing each other, such as in a landscape orientation, or the second edge of each facing each other, such as in a portrait orientation. In either event, the tap on each panel will be proximate each other to minimize electrical interconnection distance.

### RELATED APPLICATION DATA

The present application is a continuation-in-part of commonly owned application for Solar-Cell Module with In-laminate Diodes and External-Connection Mechanisms Mounted to Respective Edges, Ser. No. 12/121,602, filed May 15, 2008, the specification of which is incorporated herein as if fully set forth.

### BACKGROUND OF THE INVENTION

1. Field of the Invention

The present invention relates generally to solar panels and more particularly to an interconnection system in which an electrical connection length between adjacent panels during field installation is minimized irrespective of orientation of such panels within an array.

2. Description of the Related Art

A typical solar panel includes a plurality of individual solar cells aggregated and electrically interconnected so that the electrical current developed by each individual cell in response to solar energy incident thereon is ultimately conducted to a current collector node, which may exemplarily be a bus bar, within the panel. The details of various methods for and systems of the aggregation and interconnection of each cell within the panel are well known and need not be further described herein.

The typical solar panel may include a tap accessible at the exterior of the panel to facilitate electrical connection to the current collector node of the panel. The solar panel may also include another tap accessible at the exterior of the panel to facilitate electrical connection to a common reference node, which may exemplarily be another bus bar, within the panel. The tap to the current collector node may be indicated by a (+) polarity and the tap to the common reference node may be indicated by a (−) polarity.

A single solar panel of the type presently commercial available for commercial and residential installations generally provides a relatively low power output, typically in a range of 150-200W at 15-20VDC and 5-10A. Accordingly, in a residential or commercial installation, many such panels must be used to provide a useful amount of power.

The panels in any such installation are typically mounted to a roof top rack and disposed in a two dimensional array. The plane of the array is oriented to maximize the collection of solar energy in each panel so that upon its conversion to electrical energy the maximum power output available from each panel can be obtained, thus maximizing the power output from the array as a whole. To maximize the effective surface area of the array, this generally being the sum of the active surface area for all of the panels in the array, the panels are mounted edge to edge with the smallest gap possible between adjacent panels being provided to compensate for thermal expansion. It is also recognized that the active surface area of each panel is less than its total surface area as the solar cells therein cannot extend completely to the edges at which there is provided sealing of a typical panel laminate structure, and further that non-active space exists between individual cells or submodules of cells within the panel.

Most such panels come in a variety of sizes, and typically are rectangular with a width generally between 50-60% of the length. Of course, to construct any two dimensional array having the maximum effective surface area, all panels in the array must have the same length and width. At the time of field installation of the panels into an array, a simple calculation based on the overall dimensions of the installation site and the dimensions of the panels to be used readily determines if a landscape or portrait orientation of each of the panels provides for the maximum number of panels that can be utilized to obtain the maximum effective surface area of the resultant array.

Because of the relatively low power output of each panel, and the number of panels required to achieve usable amounts of power, substantial efforts in the art have been directed to the minimization of electrical losses both within the internal circuitry of the panels and the external interconnections between panels and of the arrays to external loads. Every connector and each length of cable used in the array has associated therewith a resistance. When current flows through any such connector or cable, a voltage drop occurs across such connector or cable and some power is lost through its resistance as dissipated heat.

To provide the above mentioned taps needed to interconnect adjacent panels, many such commercially available panels have a junction box providing access to such taps disposed on the bottom surface of the panel so as not to interfere with solar energy collection. The installer may then run appropriate weather resistant cables between each junction box on two adjacent panels, for example in a series connection from the (+) tap of one such panel to the (−) tap on the next adjacent panel in a row or column in the array. If the panels are disposed in a portrait configuration relative to the electrical connection to be made between adjacent panels, the distance between each junction box on each of adjacent identically manufactured panels is substantially commensurate with the width of the panel. Conversely, if the panels are disposed in a landscape configuration relative to the electrical connection to be made, the distance between each junction box on each of these same panels is substantially commensurate with the length of the panel.

If the interconnection cables are installed during field installation, then the cable lengths between identically manufactured panels can be minimized by mounting the panels in the portrait configuration. However, as stated above, the installation site may require that these panels be array mounted in the landscaped configuration to maximize the number of panels in the array. Although the overall power output the entire array is increased, the increase is less than the sum total of the power of the additional panels due to the increased resistive losses in the longer cables needed for panel interconnection.

Moreover, some commercially available panels are manufactured with weather resistant cables leading from the junction box with mating weather proof connectors, which may further be provided in (+) and (−) polarity configurations, provided at the free end thereof. The length of the preinstalled cable must accordingly be sufficient to mate with the corresponding cable of the adjacent panel irrespective of the portrait or landscape orientation of the panels. Thus, the maximum length of cable must always be used, resulting in maximum resistive losses in the cables, to allow landscape orientation even if the panels are array mounted in a portrait configuration.

In the co-pending application above referenced, it is disclosed that each solar panel may have a pair of junction boxes, wherein each junction box is disposed adjacent a respective one of opposite edges of the panel along a line normal to such opposite edges. If the edge chosen is the short edge along the width of the panel, then as the panels are array mounted edge to edge in a landscape configuration the junction boxes on facing edges of two adjacent panels will accordingly be aligned and proximate to each other, thereby minimizing the electrical connection distance between the junction boxes on facing edges of the panels and thus minimizing the length of cable needed. As the length of all such cables used to connect each panel in each landscaped configured row is minimized, resistive losses due to cable lengths is accordingly minimized.

Another advantage of using two junction boxes per panel is that each junction box on a single panel can have a respective one of the (+) or (−) polarity taps associated therewith. As the panels are array mounted edge to edge in the landscape configuration the tap of the junction box on the edge of one panel will have the opposite polarity to the polarity of the tap of the junction box at the facing edge of the adjacent panel.

By providing on each panel two junction boxes, each respectively associated with one of the (+) or (−) polarities, the internal bus bars in each panel for common reference and the current collector node may then advantageously have a minimal length by obviating the need to extend each of these bus bars across the total length of the panel to provide connection thereto at each junction box or, as in the case of the commercially available panels described above, to the single junction box wherever located on the panel. The common and current collector bus bars need only extend across the width of the panel in this example, assuming that individual solar cells along a common row along the length are series connected for maximum output voltage. Since any conductor has a resistance per unit length, this decreased length thereby decreases resistive losses within the panel. A further advantage arises from the savings of material and fabrication costs of each panel.

However, if those same panels need to be mounted edge to edge in a portrait configuration, then the junction boxes of adjacent panels that need to be interconnected become separated by a distance substantially commensurate with the dimension of the diagonal of the panel. As this diagonal has a dimension greater in magnitude than the length of the panel, the length of the cable required becomes even longer, and the resistive losses due to cable length even greater, than the cable required for a portrait configuration in the commercially available panels with one junction box.

Similarly, if the two junction boxes are configured for minimal interconnect distance between portrait oriented panels, in which each of the junction boxes is mounted along a respective one of the long edges along a line normal to the opposite long edges, then should a landscape orientation be necessitated the cable length required is again substantially commensurate with the dimension of the diagonal of the panel. Even if the junction boxes are placed at a corner of the panel, but at opposite ends of the long edge for optimal landscape orientation or at opposite ends of the short edge for optimal portrait configuration, then the use of such panels in their respective non-optimized configuration will always result in a cable length substantially commensurate with the dimension of the diagonal of the panel.

Another consideration, in addition to resistive losses incurred through excessive cable lengths, is the cost of the cable itself. Cable that is typically used during field installation of solar panels generally costs between $0.20-0.25 per foot. Clearly, should maximum cable lengths for panel to panel interconnection, as in the examples set forth above, be required for a typically sized array the cost of the cable would be significantly increased as compared to adjacent panels having closely disposed junction boxes on the edges thereof.

Accordingly, a need exists to provide a solar panel interconnection system in which the electrical interconnect distance between panels is always optimally minimized irrespective of whether such panels are oriented in a portrait or landscape configuration.

### SUMMARY OF THE INVENTION

According to the present invention, a solar panel interconnection system in which electrical interconnection distance is minimized irrespective of one of a first panel orientation and a second panel orientation includes a first solar panel having first diagonally opposed corners, a first edge, a second edge and a tap adapted to provide electrical connectivity to the first solar panel, and a second solar panel having second diagonally opposed corners, a first edge, a second edge and a tap adapted to provide electrical connectivity to the second solar panel. The first edge and the second edge of the first solar panel extend from one of the first diagonally opposed corners and the tap on the first solar panel is disposed at the same corner thereof. The first edge and the second edge of the second solar panel extend from one of the second diagonally opposed corners and the tap on the second solar panel is disposed at the same corner thereof.

Upon the first solar panel and the second solar panel each being disposed in a selected one of the first orientation and the second orientation in which for the first orientation the first edge of the first solar panel and the first edge of the second solar panel are proximately disposed in a facing relationship to each other and in which for the second orientation the second edge of the first solar panel and the second edge of the second solar panel are proximately disposed in a facing relationship to each other, the first diagonally opposed corners and the second diagonally opposed corners mirror image each other with the one of the first diagonally opposed corners being proximate the one of the second diagonally opposed corners. As the tap on the first solar panel and the tap on the second solar panel are also disposed at these proximately disposed corners, the taps also become proximately disposed to each other. The electrical interconnection distance between the tap on the first solar panel and the tap on the second solar panel is therefore minimized irrespective of whether the first orientation or the second orientation is selected.

A feature of the present invention is that when such first and second solar panels are disposed in an array, taps to be connected to each other in any one row or column of the array are always proximate each other thereby advantageously minimizing cable lengths between panels. Accordingly, the total resistive losses due to electrical interconnection cables and also the cost of such cables in the array are also advantageously minimized.

These and other objects, advantages and features of the present invention will become readily apparent to those skilled in the art from a study of the following Description of the Exemplary Preferred Embodiments when read in conjunction with the attached Drawing and appended Claims.

### BRIEF DESCRIPTION OF THE DRAWING

FIG. 1A shows a first solar panel and a second solar panel constructed in accordance with the principles of the present invention disposed in a first coplanar orientation;

FIG. 1B shows the first solar panel and the second solar panel of FIG. 1A disposed in a second coplanar orientation;

FIG. 2A shows array of first solar panels and second solar panels in a landscape orientation with respect to an electrical connection along a row of the array;

FIG. 2B shows array of first solar panels and second solar panels in a portrait orientation with respect to an electrical connection along a row of the array;

FIG. 3 shows a corner detail of a solar panel of FIG. 1;

FIG. 4A-B show an exemplary junction box and electrical interconnection made between the first and second solar panels.

### DESCRIPTION OF THE EXEMPLARY PREFERRED EMBODIMENTS

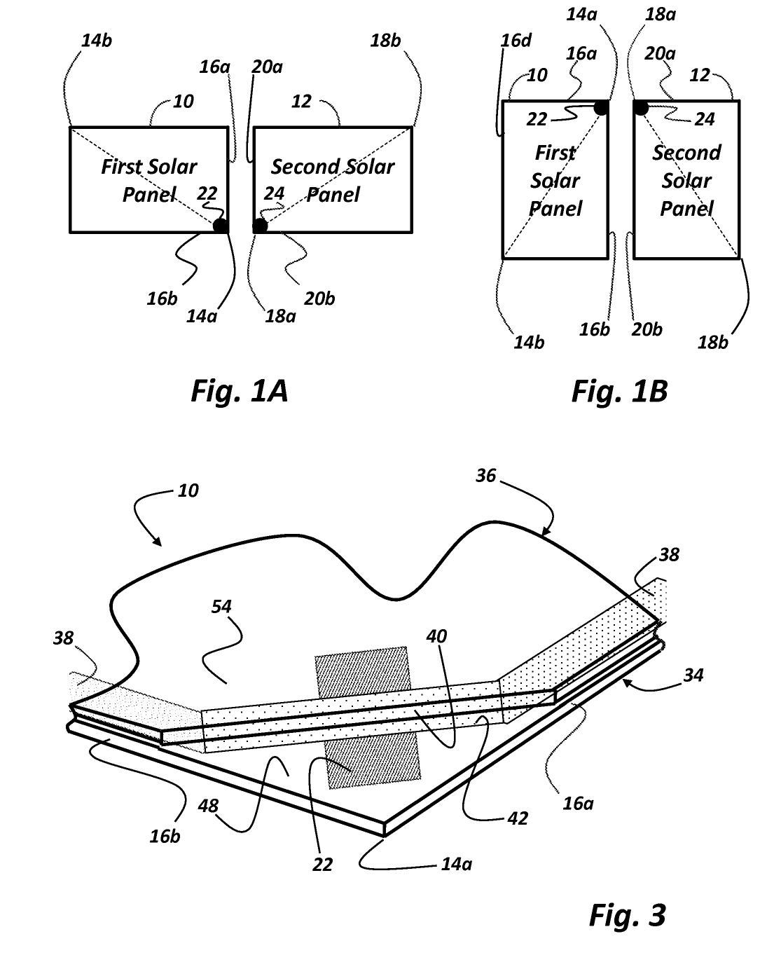

Referring now to FIGS. 1A-1B, there is shown a first solar panel 10 and a second solar panel 12. The first solar panel 10 has first diagonally opposed corners, 14a, 14b and a first edge 16a and a second edge 16b extending from one of the first diagonally opposed corners 14a, 14b, exemplarily shown herein as corner 14a. Similarly, the second solar panel 12 has second diagonally opposed corners, 18a, 18b and a first edge 20a and a second edge 20b extending from one of the second diagonally opposed corners 18a, 18b, exemplarily shown herein as corner 18a.

The first solar panel 10 further has a tap 22 disposed thereon at one of the first diagonally opposed corners 14a, 14b from which each of the first edge 16a and the second edge 16b of the first solar panel 10 extends, exemplarily shown herein as corner 14a. Similarly, the second solar panel 12 has a tap 24 disposed thereon at one of the second diagonally opposed corners 18a, 18b, from which each of the first edge 20a and the second edge 20b of the second solar panel 12 extends, exemplarily shown herein as corner 18a. The tap 22 on the first solar panel 10 and the tap 24 on the second solar panel 12 each provide electrical connectivity respectively thereto.

When the first solar panel 10 and the second solar panel 12 are disposed, for example during field installation, in the first orientation of FIG. 1A, the first edge 16a of the first solar panel 10 and the first edge 20a of the second solar panel 12 are proximately disposed in a facing relationship to each other. Alternatively, when the first solar panel 10 and the second solar panel 12 are disposed in the second orientation of FIG. 1B, the second edge 16b of the first solar panel 10 and the second edge 20b of the second solar panel 12 are proximately disposed in a facing relationship to each other. It is to be noted that, as seen in FIGS. 1A-1B and in any other figure of the Drawing herein, the gap shown between the first solar panel 10 and the second solar panel 12 is highly exaggerated for clarity of illustration only.

As readily seen in FIGS. 1A and 1B, in either orientation the first diagonally opposed corners 14a, 14b of the first solar panel 10 mirror image the second diagonally opposed corners 18a, 18b of the second solar panel 12 with the corner 14a of the first solar panel 10 being proximate the corner 18a of the second solar panel 12. This mirror image is readily seen along a diagonal of the first solar panel 10 originating at the corner 14a with the tap 22 and extending to the corner 14b and along a diagonal of the second solar panel 12 originating at the corner 18a with the tap 24 and extending to the corner 18b.

As a result of this mirror image, the tap 22 at the corner 14a on the first solar panel 10 and the tap 24 at the corner 18a on the second solar panel 12 are proximately disposed to each other. Accordingly, irrespective of orientation, the electrical connection distance between the tap 22 on the first solar panel 10 and the tap 24 on the second solar panel 12 is minimized, thus minimizing electrical resistance due to the electrical interconnect cable used in such connection.

Utilizing the principles of the present invention as described in conjunction with the first solar panel 10 and the second solar panel 12 of FIGS. 1A and 1B, an array of solar panels can readily be constructed in which electrical connection distances between adjacent panels are minimized, irrespective of whether the array is constructed in which all the solar panels are in a portrait or landscape orientation relative to the electrical connection made between panels. By minimizing the length of cable required between any two panels, the total cable length used for interconnection of panels in the array is minimized and thus the electrical resistance in the array due to such interconnect cables is accordingly minimized.

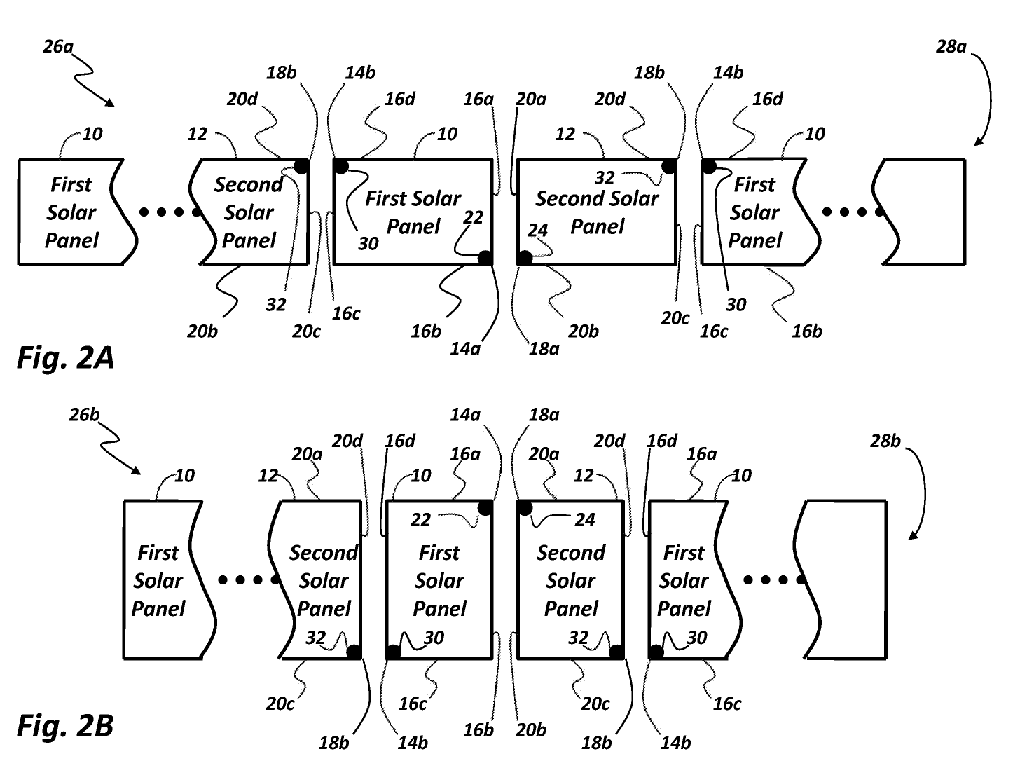

Referring now to FIGS. 2A-2B, there is shown an array 26a (FIG. 2A) and an array 26b (FIG. 2B) constructed from a plurality of the first solar panels 10 being alternatingly disposed with the second solar panels 12. As best seen in FIG. 2A, the first and second solar panels 10, 12 are in a landscape orientation with respect to the electrical connection to be made along an exemplary row 28a of the array 26a. As best seen in FIG. 2B, the first and second solar panels 10, 12 are in a portrait orientation with respect to the electrical connection to be made along an exemplary row 28b of the array 26b.

It is to be noted that the exemplary row 28a of the array 26a as seen in FIG. 2A and the exemplary row 28b of the array 26b as seen in FIG. 2B illustrate just a partial portion of only one row, which may be repeated as often as necessary during field installation of the array 26a of FIG. 2A or the array 26b of FIG. 2B. Furthermore, additional ones of each of the first solar panel 10 and the second solar panel 12 may be alternatingly disposed across all such rows. Should the electrical connections in either the array 26a of FIG. 2A or the array 26b of FIG. 2B be made in a column instead of a row thereof, the same principles as herein described apply and need not be separately set forth in that the landscape and portrait orientation of the panels are taken with respect to the orientation of the panels with respect to whether adjacent panels are electrically connected linearly along a row or column.

Each of the first solar panels 10 further has a third edge 16c and a fourth edge 16d extending from the other one of the diagonally opposed corners 14a, 14b, exemplarily shown herein as corner 14b. More particularly, in each of the first solar panels 10 the third edge 16c is opposite the first edge 16a and the fourth edge 16d is opposite the second edge 16b. Similarly, each of the second solar panels 12 further has a third edge 20c and a fourth edge 20d extending from the other one of the diagonally opposed corners 18a, 18b, exemplarily shown herein as corner 18b. More particularly, in each of the second solar panels 12 the third edge 20c is opposite the first edge 20a and the fourth edge 20d is opposite the second edge 20b.

In addition to the tap 22, each of the first solar panels 10 has a further tap 30 disposed thereon at the other one of the first diagonally opposed corners 14a, 14b from which each of the third edge 16c and the fourth edge 16d of the first solar panel 10 extends, exemplarily shown herein as corner 14b. Similarly, in addition to the tap 24, each of the second solar panels 12 has a further tap 32 disposed thereon at the other one of the first diagonally opposed corners 18a, 18b from which each of the third edge 20c and the fourth edge 20d of the second solar panel 12 extends, exemplarily shown herein as corner 18b.

When the plurality of the first solar panels 10 and the second solar panels 12 are alternatingly disposed along the exemplary row 28a in the landscape orientation of FIG. 2A, the first edge 16a of each of the first solar panels 10 respectively in one of the i^{th}, i^{th}+2 . . . i^{th}+n positions, wherein i is any nonzero integer and n is an even integer, and the first edge 20a of each of the second solar panels 12 respectively in one of the next adjacent i^{th}+1, i^{th}+3 . . . i^{th}+n+1 positions along the same row are proximately disposed in a facing relationship to each other. Furthermore, the third edge 16c of each of the first solar panels 10 respectively in one of the i^{th}, i^{th}+2 . . . i^{th}+n positions and the third edge 20c of each of the second solar panels 12 respectively in one of the previously adjacent i^{th}-1, i^{th}+1 . . . i^{th}+n−1 positions along the same row are proximately disposed in a facing relationship to each other.

Alternatively, when the plurality of the first solar panels 10 and the second solar panels 12 are alternatingly disposed along the exemplary row 28b in the portrait orientation of FIG. 2B, the second edge 16b of each of the first solar panels 10 respectively in one of the i^{th}, i^{th}+2 . . . i^{th}+n positions and the second edge 20b of each of the second solar panels 12 respectively in one of the next adjacent i^{th}+1, i^{th}+3 . . . i^{th}+n+1 positions along the same row are proximately disposed in a facing relationship to each other. Furthermore, the fourth edge 16d of each of the first solar panels 10 respectively in one of the i^{th}, i^{th}+2 . . . i^{th}+n positions and the fourth edge 20d of each of the second solar panels 12 respectively in one of the previously adjacent i^{th}-1, i^{th}+n−1 . . . i^{th}+n−1 positions along the same row are proximately disposed in a facing relationship to each other.

In either the landscape orientation of FIG. 2A or the portrait orientation of FIG. 2B, the first diagonally opposed corners 14a, 14b of the each of the first solar panels 10 in any i^{th} position mirror image the second diagonally opposed corners 18a, 18b of each of the second solar panels 12 in the previously adjacent i^{th}-1 or next adjacent i^{th}+1 position. More particularly, the corner 14a of each of the first solar panels 10 is proximate the corner 18a of the next adjacent one of the second solar panels 12 and the corner 14b of each of the first solar panels 10 is proximate the corner 18b of the previously adjacent one of the second solar panels 12.

As a result of this mirror image similarly as described above, the tap 22 at the corner 14a on the each of the first solar panels 10 in any i^{th} position and the tap 24 at the corner 18a on each of the second solar panels 12 in the next adjacent i^{th}+1 position are proximately disposed to each other and the tap 30 at the corner 14b on the each of the first solar panels 10 in any i^{th} position and the tap 32 at the corner 18b on each of the second solar panels 12 in the previously adjacent i^{th}-1 position are proximately disposed to each other. Accordingly, irrespective of orientation, the electrical connection distance between the tap 22 on each of the first solar panels 10 and the tap 24 on the next adjacent one of the second solar panels 12 and between the tap 30 on each of the first solar panels 10 and the tap 32 on the previously adjacent one of the second solar panels 12 is minimized. Therefore, the electrical resistance due to electrical interconnection cables in either the landscape array 26a or the portrait array 26b, as well as the costs of such cables used, is also minimized.

Exemplarily, for an electrical connection along any row as described above, the tap 22 on each of the first solar panels 10 may have a (+) polarity associated therewith and the proximately disposed tap 24 on the next adjacent one of each of the second solar panels 12 may have a (−) polarity associated therewith. In such example, the tap 30 on each of the first solar panels 10 would then have a (−) polarity associated therewith and the proximately disposed tap 32 on the previous adjacent one of each of the second solar panels 12 would then have a (+) polarity associated therewith.

By mirror imaging only the corners at which the afore described taps are located in adjacent panels, the internal circuitry of the first solar panel 10 and the second solar panel 12 can advantageously be of identical manufacture. Only the internal reference bus bar and current collector bus bar need be tapped at the appropriate corner of the identically manufactured panels to construct either the first solar panel 10 or the second solar panel 12 and provide the polarity to be associated with the tap at such corner.

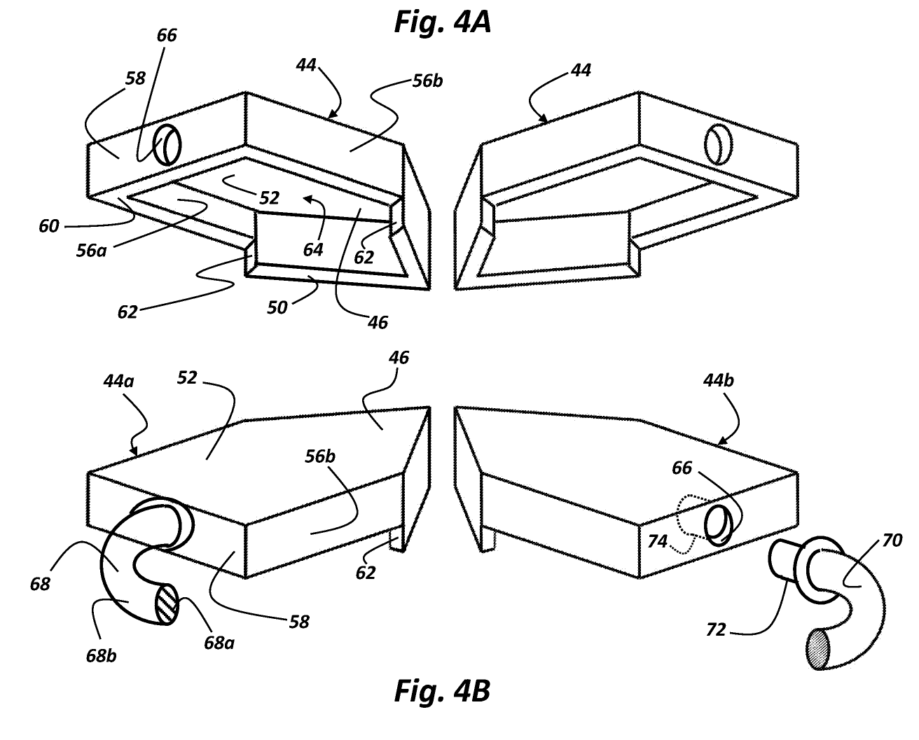

With reference now to FIG. 3, the first solar panel 10 generally includes a front layer 34, which is substantially transparent to solar energy, and a back protective layer 36 at which the afore described taps are accessible so as not to interfere with solar collection at the front layer 34. The front layer 34 and the back protective layer 36 are sealed together by a sealant layer 38 disposed coextensive with the edges 16a-d of the first solar panel.

The material of the front layer 34 may typically be glass as glass is transparent to solar energy and weather resistant. The material of the back protective layer may also be glass, however, other materials such as lightweight flexible materials and laminates are well known for providing the requisite sealing of the front layer 34 and the back protective layer 36 to each other to isolate the interior of the solar cell panel from external ambient conditions. The sealant layer 38 may exemplarily be a polymeric sealant. The second solar panel 12 is of similar construction such that the details of the construction described herein with specific reference to the first solar panel 10 apply equally to the corresponding elements of the second solar panel 12.

The tap 22 is made accessible at an opening in the first solar panel 10 proximate the corner 14a thereof. This opening, which may be any type of bore, cut, slice, knockout or the like, may be disposed with the void in the planar surface of either the front layer 34 or the back protective layer 26 of the first solar panel 10, disposed with the void along the first edge 16a or second edge 16b interstitially or within either or both of the of the front layer 34 and the back protective layer 26, or disposed with the void being removing part of such planar surface and the contiguous edge thereto. This opening may also either expose a portion of an underlying bus bar within the first panel 10 or such bus bar may be extended through any such opening. The integrity of the sealant between the front layer 34 and the back protective layer 26 is nonetheless maintained at any such opening. The other diagonally opposed corner 14b of the first solar panel 10, and both of the diagonally opposed corners 18a-b of the second solar panel 12, may be constructed identically as described for the corner 14a herein.

In the embodiment shown in FIG. 3, the opening for the tap 22 is shown as a cut in the back protective layer 36 along a line extending between the first edge 16a and the second edge 16b of the first solar panel 10 and over the sealant layer 38 such the back protective layer 36 remains sealed to the front layer 34 along a cut edge 40 of the back protective layer 36. The cut edge 40 exposes the tap 22, which may be an extended portion of a bus bar within the first solar panel 10 or otherwise electrically connected thereto. The tap 22 is preferably constructed from a suitable flexible electrical conductor. A further sealant layer 42 may also be disposed coextensive with the cut edge 40 such that the tap 22 is disposed intermediate the sealant layer 38 and the further sealant layer 42.

With respect to the tap 22 at the corner 14a of the first solar panel 10 and the tap 32 at the corner 18b of the second solar panel 12, if these taps 22, 32 are to be associated with the (+) polarity, the tap 22 exposed by the cut edge 40 at the corner 14a and the tap 32 exposed at the corner 18b are each extensions of or otherwise connected to the current collector bus bar in the respective first solar panel 10 and second solar panel 12. Similarly, with respect to the tap 30 at the corner 14b of the first solar panel 10 and the tap 24 at the corner 18a of the second solar panel 12, if these taps 30, 24 are to be associated with the (−) polarity, the tap 30 exposed by the cut edge 40 at the corner 14b and the tap 24 exposed at the corner 18a are each extensions of or otherwise connected to the reference bus bar in the respective first solar panel 10 and second solar panel 12.

In some field installations, it may be desirable to protect the opening in the back protective layer 36 from environmental elements with a simple junction box disposed over the opening. The junction box also provides an enclosure for electrical connections made to the tap disposed within its enclosure.

Referring now to FIG. 4A, there is shown a detailed representation of an exemplary embodiment of a junction box 44 useful to mount to the corner 14a of the first solar panel 10 having the cut edge 40 as described in FIG. 3. The junction box 44 is dimensioned commensurately with the corner 14a such that a first generally triangular portion 46 thereof is disposed over an inner surface 48 (FIG. 3) of the front layer 34 exposed by the cut edge 40. The triangular portion has a lower edge 50 that may be sealed to the inner surface 48 of the front layer 48 where exposed by the cut edge 40 and substantially flush with the first edge 16a and second edge 16b.

The junction box 44 further has a second generally rectangular portion 52 extending inwardly from the triangular portion 46 over an outer surface 54 (FIG. 3) of the back protective layer 36. When the triangular portion 46 is dimensioned as described above, the dimension of the rectangular portion 52 between its sidewalls 56a, 56b is accordingly commensurate with the length of the cut edge 40. The rectangular portion 52 also has an end wall 58.

Coextensive with the sidewalls 56a, 56b and the end wall 58, the rectangular portion 52 has a lower edge 60 may be sealed to the outer surface 54 of the back protective layer 36. The lower edge 60 of the rectangular portion 52 is offset from the lower edge 50 of the triangular portion 46 by a dimension commensurate with the thickness of the back protective layer 36, thereby exposing an offset edge 62 between the lower edge 60 of the rectangular portion 52 and the lower edge 50 of the triangular portion 46. The offset edge 62 may be sealed to the cut edge 40.

When mounted and sealed as above, the junction box 44 forms a weatherproof chamber 64 in which electrical connection may be made to the tap 22. The end wall 58 may include an opening 66 for access to the tap 22. The connection of the external cable to the tap 22 with the chamber 64 may be made by any conventional means such as lugs and the like.

Other junction boxes identical in construction to the junction box 44 may also be mounted to the respective corners 18a, 14b, 18b as described for the junction box 44 with respect to corner 14a. In such case an external cable may be field installed, for example between the proximately disposed junction boxes each of the first solar panels 10 and the adjacent one of the second solar panels 12. For example, one such cable would be connected by conventional means to the tap 22 accessible at the corner 14a of the first solar panel 10 and extend through the opening 66 preferably using known weatherproof connectors for cables and junction boxes. Using an identical junction box 44 at the corner 18a of the second solar panel, the cable would be installed through the opening 66 and connected by conventional means to the tap 24 accessible at the corner 18a of the second solar panel 12.

With further reference to FIG. 4B, when the junction boxes 44 protect taps with a polarity as above described, the junction boxes over taps with the (+) polarity may have a cable factory installed to facilitate connection during field installation to the associated junction boxes, which may then have a socket to receive such cable, over taps with the (−) polarity. Accordingly, the exemplary junction box 44a on the first solar panel 10 may have a cable 68 connected to the tap 22 accessible at the corner 14a by conventional means and extending through the opening 66. A distal end 70 of the cable 68 may have a conventional weatherproof electrical connector 72.

The junction box 44b at the second solar panel 12, which is proximate the junction box 44a on the first solar panel 10, may then have disposed in the opening 66 a socket 74 adapted to receive the electrical connector 72. The socket 74 is electrically connected by conventional means to the tap 24 accessible at the corner 18a of the second solar panel 12. Conventional mating male and female electrical connectors disposed respectively in one of the connector 72 and the socket 74 complete the electrical connection when the connector 72 is received within the socket 74. The cable 68 may be bare cabled or further have a conductive core 68a and an insulator layer 68b.

There has been described herein novel apparatus and techniques for providing electrical connection between adjacent solar panels to minimize electrical connection distances and hence minimize resistive losses. Those skilled in the art may now make numerous uses of and departures from the herein above described embodiments without departing from the inventive concepts disclosed herein. Accordingly, the present invention is to be defined solely by the lawfully permitted scope of the appended Claims.

What is claimed as the invention is:

1. A solar panel interconnection system in which electrical interconnection distance is minimized irrespective of one of a first panel orientation and a second panel orientation for said system, said solar panel system comprising:
a first solar panel having first diagonally opposed corners, a first edge, a second edge and a tap to which electrical connection to said first solar panel is made, said first edge and said second edge extending from one of said first diagonally opposed corners, said tap being disposed proximately to one of said first diagonally opposed corners; and
a second solar panel having second diagonally opposed corners, a first edge, a second edge and a tap to which electrical connection to said second solar panel is made, said first edge and said second edge of said second solar panel extending from one of said second diagonally opposed corners thereof, said tap of said second solar panel being disposed proximately to said one of said second diagonally opposed corners;
wherein, upon said first solar panel and said second solar panel each being disposed in a selected one of said first orientation and said second orientation in which for said first orientation said first edge of said first solar panel and said first edge of said second solar panel are proximately disposed in a facing relationship to each other and in which for said second orientation said second edge of said first solar panel and said second edge of said second solar panel are proximately disposed in a facing relationship to each other, said first diagonally opposed corners and said second diagonally opposed corners mirror image each other with said one of said first diagonally opposed corners being proximate said one of said second diagonally opposed corners such that said tap on said first solar panel and said tap on said second solar panel are proximately disposed to each other, whereby said electrical interconnection distance between said tap on said first solar panel and said tap on said second solar panel is minimized irrespective of said selected one of said first orientation and said second orientation.

2. A solar panel interconnection system as set forth in claim 1 wherein each of said first solar panel and said second solar panel includes a front layer substantially transparent to solar energy, a back protective layer and an opening, said tap of each of said first solar panel and said second solar panel respectively being made accessible at said opening, said opening having a void disposed in a selected one of said front layer and said back protective layer in one of a planar surface and an edge thereof.

3. A solar panel interconnection system as set forth in claim 2 wherein said opening of said first solar panel is disposed in said back protective layer thereof and said opening of said second solar panel is disposed in said back protective layer thereof.

4. A solar panel interconnection system as set forth in claim 3 wherein said tap of each of said first solar panel and said second solar panel is respectively exposed by said opening in said back protective layer thereof.

5. A solar panel interconnection system as set forth in claim 3 wherein said tap of at least one of said first solar panel and said second solar panel respectively extends through said opening in said back protective layer thereof.

6. A solar panel interconnection system as set forth in claim 5 wherein said tap of each of said first solar panel and said second solar panel is constructed from a flexible electrically conductive material.

7. A solar panel interconnection system as set forth in claim 2 wherein said back protective layer is a flexible material.

8. A solar panel interconnection system as set forth in claim 7 wherein said material is a laminate.

9. A solar panel interconnection system as set forth in claim 2 wherein said back protective layer is glass.

10. A solar panel interconnection system as set forth in claim 2 wherein said first solar panel further includes a cable in electrical communication with said tap of said first solar panel and said second solar panel further includes a socket in which electrical connection to said tap of said second solar panel is provided disposed in said back protective layer of said second solar panel, said cable having a distal end and a connector disposed at said distal end such that electrical connection is established between said tap of said first solar panel and said tap of said second solar panel upon said connector being received within said socket.

11. A solar panel interconnection system as set forth in claim 10 wherein said cable and said tap of said first solar panel are of unitary construction.

12. A solar panel interconnection system as set forth in claim 10 wherein said cable includes an inner conductor in electrical communication with said tap of said first solar panel and an outer weatherproof insulator.

13. A solar panel interconnection system as set forth in claim 2 wherein said first solar panel includes a junction box on said back protective layer disposed over said tap thereof and said second solar panel includes a junction box on said back protective layer disposed over said tap thereof.

14. A solar panel interconnection system as set forth in claim 13 wherein said back protective layer of said first solar panel includes a cut edge at said one of said first diagonally opposed corners extending between said first edge and said second edge thereof and said back protective layer of said second solar panel includes a cut edge at said one of said second diagonally opposed corners extending between said first edge and said second edge thereof, said tap of said first solar panel being exposed by said cut edge in said back protective layer thereof and said tap of said second solar panel being exposed by said cut edge in said back protective layer thereof.

15. A solar panel interconnection system as set forth in claim 14 wherein each of said first solar panel and said second solar panel includes a first sealant layer coextensive with said first edge and said second edge thereof and further includes a second sealant layer coextensive with said cut edge in said back protective layer thereof, said tap of each of said first solar panel and said second solar panel being disposed intermediate said first sealant layer and said second sealant layer.

16. A solar panel interconnection system as set forth in claim 14 wherein said front layer of each of said first solar panel and said second solar panel has an inner surface, and further wherein said junction box on said first solar panel and said junction box on said second solar panel each have a generally triangular portion, said triangular portion of said junction box on said first solar panel being disposed over said inner surface thereof exposed by said cut edge at said one of said first diagonally opposed corners of said first solar panel and said triangular portion of said junction box on said second solar panel being disposed over said inner surface thereof exposed by said cut edge at said one of said second diagonally opposed corners of said first solar panel, said junction box on said first solar panel and said junction box on said second solar panel each respectively having an opening through which said tap of said first solar panel and said second solar panel is accessible.

17. A solar panel interconnection system as set forth in claim 16 wherein said back protective layer of each of said first solar panel and said second solar panel has an outer surface, and further wherein said junction box on said first solar panel has a generally rectangular portion extending inwardly from said triangular portion thereof over said outer surface of said first solar panel and said junction box on said second solar panel has a generally rectangular portion extending inwardly from said triangular portion thereof over said outer surface of said second solar panel, said rectangular portion having an end wall in which said opening is disposed.

18. A solar panel interconnection system as set forth in claim 17 wherein said junction box on said first solar panel further has a cable extending through said opening in said wall of said rectangular portion thereof and said junction box on said second solar panel has a socket in which electrical connection to said tap of said second solar panel is provided disposed in said opening in said end wall of said rectangular portion thereof, said cable being in electrical communication with said tap of said first solar panel and having a distal end and an electrical connector disposed at said distal end, said electrical connector being adapted to be received by said socket such that electrical connection is established between said tap of said first solar panel and said tap of said second solar panel.

19. A solar panel interconnection system as set forth in claim 18 wherein said rectangular portion further has a pair of side walls extending between said rectangular portion and said end wall wherein a dimension of said rectangular portion between said side walls is commensurate with a length of said cut edge.

20. A solar panel interconnection system as set forth in claim 1 wherein said tap of said first solar panel is associated with a (+) polarity and said tap of said second solar panel is associated with a (−) polarity.

21. A solar panel interconnection system in which electrical interconnection distance is minimized irrespective of one of a landscape orientation and portrait orientation for said system, said solar panel system comprising:
a plurality of first solar panels, each of said first solar panels having first diagonally opposed corners, a first edge, a second edge, a third edge, a fourth edge and a pair of taps to which electrical connection to each of said first solar cells is respectively made, said first edge and said second edge of each of said first solar panels extending from one of said first diagonally opposed corners thereof and said third edge and said fourth edge of each of said first solar panels extending from one other of said diagonally opposed corners, said third edge of each of said first solar panels being opposite said first edge thereof and said fourth edge of each of said first solar panels being opposite second edge thereof, one of said taps on each of said first solar panels being disposed at said one of said first diagonally opposed corners thereof and one other of said taps on each of said first solar panels being disposed at said one other of said first diagonally opposed corners thereof;
a plurality of second solar panels, each of said second solar panels having second diagonally opposed corners, a first edge, a second edge, a third edge, a fourth edge and a pair of taps to which electrical connection to each of said second solar cells is respectively made, said first edge and said second edge of each of said second solar panels extending from one of said second diagonally opposed corners thereof and said third edge and said fourth edge of each of said second solar panels extending from one other of said second diagonally opposed corners thereof, said third edge of each of said second solar panels being opposite said first edge thereof and said fourth edge of each of said second solar panels being opposite second edge thereof, one of said taps on each of said second solar panels being disposed at said one of said second diagonally opposed corners thereof and one other of said taps on each of said second solar panels being disposed at said one other of said second diagonally opposed corners thereof;
wherein, upon said first solar panels and said second solar panels each being alternatingly disposed linearly in a selected one of said landscape orientation and said portrait orientation in which for said landscape orientation said first edge of each of said first solar panels and said first edge of a next adjacent one of said second solar panels are proximately disposed in a facing relationship to each other and said third edge of each of said first solar panels and said third edge of a previously adjacent one of said second solar panels are proximately disposed in a facing relationship to each other and in which for said portrait orientation said second edge of each of said first solar panels and said second edge of said next adjacent one of said second solar panels are proximately disposed in a facing relationship to each other and said fourth edge of each of said first solar panels and said fourth edge of said previously adjacent one of said second solar panels are proximately disposed in a facing relationship to each other, said first diagonally opposed corners and said second diagonally opposed corners mirror image each other in adjacent ones of said first solar panels and said second solar panels with said one of said first diagonally opposed corners of each of said first solar panels being proximate said one of said second diagonally opposed corners of said next adjacent one of said second solar panels and further with said one other of said first diagonally opposed corners of each of said first solar panels being proximate said one other of said second diagonally opposed corners of said previously adjacent one of said second solar panels such that said one of said taps on each of said first solar panels and said one of said taps on said next adjacent one of said second solar panels are proximately disposed to each other and further such that said one other of said taps on each of said first solar panels and said one other of said taps on said previously adjacent one of said second solar panels are proximately disposed to each other, whereby said electrical interconnect distance between said one of said taps on each of said first solar panels and said one of said taps on said next adjacent one of second solar panels and further between said one other of said taps on each of said first solar panels and said one other of said taps on said previously adjacent one of second solar panels is minimized irrespective of said selected one of said first orientation and said second orientation.

22. A solar panel interconnection system as set forth in claim 21 wherein each of said first solar panels and said second solar panels includes a front layer substantially transparent to solar energy, a back protective layer and a pair of openings, said taps of each of said first solar panels and said second solar panels being made accessible at a respective one of said openings thereof, each of said openings having a void disposed in a selected one of said front layer and said back protective layer in one of a planar surface and an edge thereof.

23. A solar panel interconnection system as set forth in claim 22 wherein each of said openings of said first solar panel is disposed in said back protective layer thereof and each of said openings of said second solar panel is disposed in said back protective layer thereof.

24. A solar panel interconnection system as set forth in claim 23 wherein said taps of each of said first solar panels and said second solar panels are exposed by said openings in said back protective layer of said first solar panels and said second solar panels.

25. A solar panel interconnection system as set forth in claim 23 wherein said one of said taps of each of said first solar panels and said one other of said taps of each of said second solar panels extends through said opening in said back protective layer of each respective one of said first solar panels and said second solar panels.

26. A solar panel interconnection system as set forth in claim 25 wherein said one of said taps of each of said first solar panels and said one other of said taps of each of said second solar panels are constructed from a flexible electrically conductive material.

27. A solar panel interconnection system as set forth in claim 22 wherein said back protective layer is a flexible material.

28. A solar panel interconnection system as set forth in claim 27 wherein said material is a laminate.

29. A solar panel interconnection system as set forth in claim 22 wherein said back protective layer is glass.

30. A solar panel interconnection system as set forth in claim 22 wherein each of said first solar panels further includes a cable in electrical communication with said one of said taps thereof and said second solar panel further includes a socket in which electrical connection to said tap of said second solar panel is provided disposed in said back protective layer of said second solar panel, said cable having a distal end and a connector disposed at said distal end such that electrical connection is established between said tap of said first solar panel and said tap of said second solar panel upon said connector being received within said socket.

31. A solar panel interconnection system as set forth in claim 30 wherein said cable and said tap of said first solar panel are of unitary construction.

32. A solar panel interconnection system as set forth in claim 30 wherein said cable includes an inner conductor in electrical communication with said tap of said first solar panel and an outer weatherproof insulator.

33. A solar panel interconnection system as set forth in claim 22 wherein each of said first solar panels includes a pair of junction boxes on said back protective layer thereof wherein each of said junction boxes for each of said first solar panels is disposed over a respective one of said taps for a same one of each of said first solar panels and each of said second solar panels includes a pair of junction boxes on said back protective layer thereof wherein each of said junction boxes for each of said second solar panels is disposed over a respective one of said taps for a same one of each of said second solar panels.

34. A solar panel interconnection system as set forth in claim 33 wherein said back protective layer of each of said first solar panels includes a cut edge at said one of said first diagonally opposed corners extending between said first edge and said second edge thereof and a cut edge at said one other of said first diagonally opposed corners extending between said third edge and said fourth edge thereof and further wherein said back protective layer of each of said second solar panels includes a cut edge at said one of said second diagonally opposed corners extending between said first edge and said second edge thereof and a cut edge at said one other of said second diagonally opposed corners extending between said third edge and said fourth edge thereof, each of said taps of each of said first solar panels being exposed by a respective one of said cut edges in said back protective layer thereof and each of said taps of each of said second solar panels being exposed by a respective one of said cut edges in said back protective layer thereof.

35. A solar panel interconnection system as set forth in claim 34 wherein each of said first solar panels and said second solar panels includes a first sealant layer coextensive with said first edge, said second edge, said third edge and said fourth edge thereof and further includes a second sealant layer coextensive with each cut edge in said back protective layer thereof, said taps of each of said first solar panel and said second solar panel being disposed intermediate said first sealant layer and said second sealant layer thereof.

36. A solar panel interconnection system as set forth in claim 34 wherein said front layer of each of said first solar panels and each of said second solar panels has an inner surface, and further wherein said pair of junction boxes on each of said first solar panels and said pair of junction box on each of said second solar panels each have a generally triangular portion, said triangular portion of one of said junction boxes and one other of said junction boxes on each of said first solar panels being disposed over said inner surface exposed by said cut edge at a respective one of said one of said first diagonally opposed corners and said one other of said first diagonally opposed corners of a same one of said first solar panels and said triangular portion of one of said junction boxes and one other of said junction boxes on each of said second solar panels being disposed over said inner surface exposed by said cut edge at a respective one of said one of said second diagonally opposed corners and said one other of said second diagonally opposed corners of a same one of said second solar panels, each of said junction boxes on each of said first solar panels having an opening through which a respective one of said taps of said same one of said first solar panels is accessible and each of said junction boxes on each of said second solar panels having an opening through which a respective one of said taps of said same one of said second solar panels is accessible.

37. A solar panel interconnection system as set forth in claim 36 wherein said back protective layer of each of said first solar panels and each of said second solar panels has an outer surface, and further wherein each of said junction boxes on each of said first solar panels has a generally rectangular portion extending inwardly from said triangular portion thereof over said outer surface of a same one of said first solar panels and each of said junction boxes on each of said second solar panels has a generally rectangular portion extending inwardly from said triangular portion thereof over said outer surface of a same one of said second solar panels, said rectangular portion having an end wall in which said opening is disposed.

38. A solar panel interconnection system as set forth in claim 37 wherein one of said junction boxes on each of said first solar panels at said one of said first corners thereof further has a cable extending through said opening in said wall of said rectangular portion thereof and one of said junction boxes at said one of said second corners on said next adjacent one of said second solar panels has a socket in which electrical connection to said one of said taps of each next adjacent one of said second solar panels is provided disposed in said opening in said end wall of said rectangular portion thereof, said cable being in electrical communication with said one of said taps of a same one of said first solar panels and having a distal end and an electrical connector disposed at said distal end, said electrical connector being adapted to be received by said socket such that electrical connection is established between said one of said taps of said same one of said first solar panels and said one of said taps of said next adjacent one of said second solar panels and further wherein one other of said junction boxes on each previous adjacent one of said second solar panels at said one other of said second corners thereof further has a cable extending through said opening in said wall of said rectangular portion thereof and one other of said junction boxes at said one other of said first corners on each of said first solar panels has a socket in which electrical connection to said one other of said taps of each of said first solar panels is provided disposed in said opening in said end wall of said rectangular portion thereof, said cable of said one other of said junction boxes on said previous adjacent one of said second solar panels being in electrical communication with said one other of said taps of a same one of said second solar panels and having a distal end and an electrical connector disposed at said distal end, said electrical connector of said cable of said one other of said junction boxes on said previous adjacent one of said second solar panels being adapted to be received by said socket of said one other of said junction boxes on said same one of said first solar panels such that electrical connection is established between said one other of said taps of said same one of said first solar panels and said one other of said taps of said previous adjacent one of said second solar panels.

39. A solar panel interconnection system as set forth in claim 38 wherein said rectangular portion further has a pair of side walls extending between said rectangular portion and said end wall wherein a dimension of said rectangular portion between said side walls is commensurate with a length of said cut edge.

40. A solar panel interconnection system as set forth in claim 21 wherein said one of said taps of each of said first solar panels and said one other of said taps of each of said second solar panels are associated with a (+) polarity and said one other of said taps of each of said first solar panels and said one of said taps of each of said second solar panels are associated with a (−) polarity.
